(19) United States
(12) Patent Application Publication
(10) Pub. No.: US 2026/0255857 A1
(43) Pub. Date: Aug. 27, 2026

(54) DISPLAY DEVICE

(71) Applicant: LG Display Co., Ltd., Seoul (KR)

(72) Inventor: Minsu KOO, Paju-si (KR)

(21) Appl. No.: 19/372,425

(22) Filed: Oct. 29, 2025

(30) Foreign Application Priority Data
Feb. 26, 2025 (KR) 10-2025-0025061

(51) Int. Cl. H10K 59/80; G06F 3/044; H10K 59/40; H10K 59/65

(52) U.S. Cl. CPC H10K 59/879; G06F 3/0446; H10K 59/40; H10K 59/65

(57) ABSTRACT

A display device includes: a display panel including a display region and an optical region which is disposed in the display region; a backplate layer disposed on the display panel; a plate layer disposed on the backplate layer in the display region; and an anti-reflective layer disposed on the backplate layer in the optical region, and the anti-reflective layer includes resin.

### CROSS REFERENCE TO RELATED APPLICATION

This application claims priority from and the benefit of Korean Patent Application No. 10-2025-0025061, filed on February 26, 2025, which is hereby incorporated herein by reference for all purposes as if fully set forth herein.

### BACKGROUND

### Field

The present disclosure relates to a display device.

### Discussion of the Background

With the progress of the information-oriented society, various types of demands for display devices which display an image are increasing. Further, various types of display devices such as a liquid crystal display device, and an organic light emitting display device have been used.

The display device includes a plurality of pixels, and a plurality of switching elements for driving and controlling the pixels.

The above information disclosed in this Background section is only for understanding of the background of the inventive concepts, and, therefore, it may contain information that does not constitute prior art.

### SUMMARY

Display devices according to embodiments of the invention are capable of preventing occurrence of a bubble phenomenon in the optical region.

Display devices according to embodiments of the invention are capable of increasing an amount of light which has passed through the optical region.

Display devices according to embodiments of the invention are capable of minimizing or at least suppressing fringe (or reflection) of light received by the sensor.

Display devices according to embodiments of the invention are capable of filling up the hole of the plate layer with the anti-reflective layer.

Display devices according to embodiments of the invention provide a low-power display device which prevents the bubble phenomenon.

The technical problem to be achieved according to embodiments of the invention is not limited to the above-mentioned technical problem, and other technical problems that are not mentioned may be inferred from the following embodiment.

Additional features of the inventive concepts will be set forth in the description which follows, and in part will be apparent from the description, or may be learned by practice of the inventive concepts.

A display device according to an embodiment of the invention includes: a display panel including a display region and an optical region which is disposed in the display region; a backplate layer disposed on the display panel; a plate layer disposed on the backplate layer in the display region; and an anti-reflective layer disposed on the backplate layer in the optical region, and the anti-reflective layer includes resin.

The anti-reflective layer may be in direct contact with a top surface of the backplate layer.

The anti-reflective layer may be in direct contact with a side surface of the plate layer.

The plate layer may include a hole defined in the optical region, and a width of the hole may be identical to a width of the anti-reflective layer.

The anti-reflective layer may be in contact with a side wall of the hole of the plate layer.

The anti-reflective layer may fill at least part of the hole of the plate layer.

A refractive index of the anti-reflective layer may have a value between a refractive index of the backplate layer and a refractive index of air.

The display device may further include a sensor disposed on the anti-reflective layer in the optical region.

The anti-reflective layer may overlap the sensor in a thickness direction.

The sensor may include an infrared sensor.

The anti-reflective layer may cover an entire region of the hole of the plate layer.

A display device according to another embodiment of the invention includes: a display panel including a display region and an optical region surrounded by the display region; a backplate layer disposed on the display panel; a plate layer disposed on the backplate layer in the display region; and an anti-reflective layer disposed on the backplate layer in the optical region, in which the display panel includes: a substrate; a first thin film transistor disposed on the substrate; a second thin film transistor disposed on the substrate and spaced apart from the first thin film transistor; a light emitting unit disposed on the substrate; an encapsulation unit disposed on the light emitting unit; a touch unit disposed on the encapsulation unit; and touch organic layers disposed on the touch unit.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic plan view of a display device according to an embodiment.

FIG. 2 is a schematic cross-sectional view taken along line A-A’ in FIG. 1.

FIG. 3 is a schematic cross-sectional view of a display panel according to an embodiment.

FIG. 4 is a schematic schematic plan view of a display device according to an embodiment.

FIG. 5 is a schematic view illustrating an arrangement of a sub-pixel in a display region, a first optical region, and a second optical region according to an embodiment.

FIG. 6 is a schematic cross-sectional view taken along line B-B’ in FIG. 1 according to an embodiment.

FIG. 7 is a schematic view illustrating light output from a sensor and light received by a sensor of a display device according to an embodiment.

FIG. 8 is a schematic cross-sectional view of a display device according to another embodiment.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

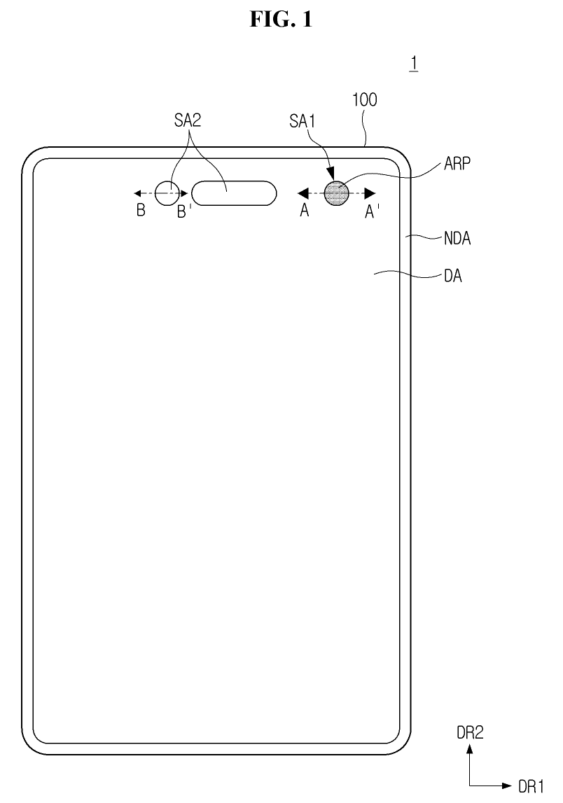

FIG. 1 is a schematic plan view of a display device according to an embodiment.

Referring to FIG. 1, the display device 1 according to an embodiment may include a display region DA including a plurality of pixels and a non-display region NDA around the display region DA. A planar shape of the display region DA may be a rectangular shape. However, it is merely an example, and the shape of the display region DA is not limited thereto. For example, the planar shape of the display region DA may be a square shape, a circular shape, an oval shape, or other polygonal shape. Furthermore, the display region DA may have a rectangular shape with rounded edges (or including a curved surface), but is not limited thereto, and may have a rectangular shape with angular edges.

A first direction DR1 and a second direction DR2 are directions different from each other and intersecting each other, and may refer to, for example, directions intersecting each other perpendicularly in a plan view. In FIG. 1, the first direction DR1 may be the same as an extending direction of short sides of the display panel 100, and the second direction DR2 may be the same as an extending direction of long sides of the display panel 100 in general. However, the direction mentioned by the embodiment should be understood as a relative direction, and the embodiment is not limited to the mentioned direction.

The display region DA may include short sides extending along the first direction DR1, and long sides extending along the second direction DR2. The non-display region NDA may surround the display region DA. The non-display region NDA may be disposed on one side of the first direction DR1, another side of the first direction DR1, one side of the second direction DR2, and another side of the second direction DR2 of the display region DA.

The display device may include optical regions SA1 and SA2 surrounded by the display region DA. The optical regions SA1 and SA2 may include a first optical region SA1 and a second optical region SA2. A planar shape of the first optical region SA1 may be a circular shape, but is not limited thereto, and may have various shapes. The second optical region SA2 may be provided in plural number, but the embodiments of the present disclosure are not limited thereto. In the optical regions SA1 and SA2, an infrared sensor or a camera sensor may be disposed. For example, an infrared sensor may be disposed in the first optical region SA1, and a camera sensor may be disposed in the second optical region SA2, but the embodiments of the present disclosure are not limited thereto.

A hole may be defined (or formed) in each of the optical regions SA1 and SA2. The hole in the optical regions SA1 and SA2 may penetrate a plate layer in a thickness direction, which will be described below.

One or more optical regions SA1 and SA2 may have a light transmitting structure for the operation of the sensor and may have a transmittance above a certain level. In particular, a quantity of the pixel per unit area in the one or more optical regions SA1 and SA2 may be fewer than a quantity of the pixel per unit area in the display region DA. More particularly, a resolution of the one or more optical regions may be lower than a resolution of the display region DA.

The light transmitting structure in the one or more optical regions may be configured by patterning a cathode electrode in a portion in which the pixel is not disposed. For example, the cathode electrode to be patterned may be removed by using a laser or may be patterned by selectively forming the cathode electrode using a material such as a cathode deposition prevention layer.

In addition, the light transmitting structure may be formed in the one or more optical region by separately forming a light emitting element and a pixel circuit in the pixel. In other words, the light emitting element of the pixel may be positioned in the optical region, a plurality of transistors forming the pixel circuit may be disposed around the optical region, and the light emitting element and the pixel circuit may be electrically connected to each other through a transparent metal layer.

According to the display panel of the display device according to an embodiment, the quantity of the pixels per area in the optical region may be fewer than the quantity of the pixels per area in the display region. Because of this, the display device may increase the amount of light which passes through the optical region.

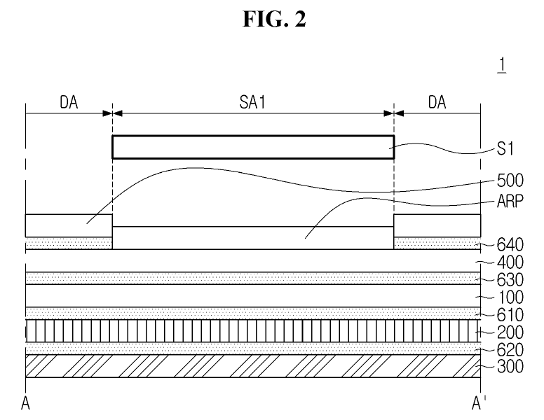

FIG. 2 is a schematic cross-sectional view taken along line A-A’ in FIG. 1.

Referring to FIG. 2, the display device 1 may include the display panel 100, a polarization layer 200, a cover layer 300, a backplate layer 400, a plate layer 500, and bonding layers 610, 620, 630 and 640. In FIG. 2, a cross-sectional view of the display device 1 in a state in which the display device 1 is turned upside down is illustrated to describe the anti-reflective layer ARP disposed in the first optical region SA1. Therefore, it is to be understood that terms of a top side (or upward) and a bottom side (or downward) in FIG. 2 are used in a relative sense.

The display panel 100 may be an organic light emitting display panel, an inorganic light emitting panel, or a liquid crystal display device etc., but the present disclosure will be described centering on an assumption that the display panel 100 is an organic light emitting display panel. For example, the display panel 100 may be a flexible display panel. The display panel 100 may be applied as a bendable or flexible display panel because it includes a flexible substrate, but the embodiments of the present disclosure are not limited thereto.

The polarization layer 200 may be disposed on a bottom portion of the display panel 100. For example, the bonding layer 610 may be disposed between the polarization layer 200 and the display panel 100. The polarization layer 200 may polarize light emitted from the display panel 100 at a polarization angle. The polarization layer 200 may release the light polarized at the polarization angle to the outside. The polarization layer 200 may include a function for blocking reflection of light except the light polarized at the polarization angle among the external light. The polarization layer 200 may include a first phase retardation layer, a second phase retardation layer on the first phase retardation layer, and the polarization layer on the second phase retardation layer. In FIG. 2, it is illustrated that the polarization layer 200 and the display panel 100 are separated from each other, but the polarization layer 200 may be included in the display panel 100, without being limited thereto. In some embodiments, the polarization layer 200 may be omitted, and a color filter may be disposed.

The cover layer 300 may be disposed below the polarization layer 200. For example, the bonding layer 620 may be disposed between the polarization layer 200 and the cover layer 300. The cover layer 300 may be formed of a glass material which includes glass or quartz, but the embodiments of the present disclosure are not limited thereto and may be formed of a plastic material. As the cover layer 300 is disposed outside the display panel 100, members disposed on the cover layer 300 may be protected from the outside. The cover layer 300 may be a cover layer formed by chemical strengthening, but the embodiments of the present disclosure are not limited thereto. The cover layer 300 may be a cover window, a window cover, or a cover member, but the embodiments of the present disclosure are not limited thereto.

The backplate layer 400 may be disposed on 100. For example, the bonding layer 630 may be disposed between the backplate layer 400 and the display panel 100. The backplate layer 400 may be disposed on the display panel 100 and may support the display panel 100. The backplate layer 400 may include a material capable of supporting the display panel 100. For example, the backplate layer 400 may include polyethylene terephthalate (“PET”), polyimide (“PI”) or polycarbonate (“PC”), but the embodiments of the present disclosure are not limited thereto. The backplate layer 400 may maintain a curvature of the display panel 100 to be constant in case that the display device 1 is folded and may suppress crease generated on an upper surface of the display panel 100.

The plate layer 500 may be disposed on the backplate layer 400. For example, the bonding layer 640 may be disposed between the backplate layer 400 and the plate layer 500. The plate layer 500 may include metal. For example, the plate layer 500 may include stainless steel, but the embodiments of the present disclosure are not limited thereto.

The bonding layers may be further disposed between the above-described members 100, 200, 300, 400, and 500. The bonding layers may include a first bonding layer 610, a second bonding layer 620, a third bonding layer 630, and a fourth bonding layer 640.

The first bonding layer 610 may be disposed between the display panel 100 and the polarization layer 200. The first bonding layer 610 may connect (or bond) the display panel 100 to the polarization layer 200.

The second bonding layer 620 may be disposed between the polarization layer 200 and the cover layer 300. The second bonding layer 620 may connect (or bond) the polarization layer 200 to the cover layer 300.

The third bonding layer 630 may be disposed between the backplate layer 400 and the display panel 100. The third bonding layer 630 may connect (or bond) the backplate layer 400 to the display panel 100.

The fourth bonding layer 640 may be disposed between the backplate layer 400 and the plate layer 500. The fourth bonding layer 640 may connect (or bond) the backplate layer 400 to the plate layer 500.

Each of the first bonding layer 610 and the second bonding layer 620 may include a clear adhesive, but the embodiments of the present disclosure are not limited thereto. For example, the clear adhesive may be a clear resin OCR, or a clear adhesive OCA, but the embodiments of the present disclosure are not limited thereto. Each of the third bonding layer 630 and the fourth bonding layer 640 may include a pressure sensitive adhesive (PSA), but the embodiments of the present disclosure are not limited thereto.

Meanwhile, in the first optical region SA1, the plate layer 500 may include a hole. For example, the hole may be defined in the plate layer 500. The plate layer 500 may not be physically separated based on the hole. It is to be understood that the plate layer 500 may not be disposed in the first optical region SA1 shown in FIG. 1 (in other words, the hole is disposed in the first optical region SA1).

The anti-reflective layer ARP may be disposed in the hole in the first optical region SA1. The anti-reflective layer ARP may be in direct contact with a top surface of the backplate 400, and in direct contact with a side surface of the plate layer 500 and the fourth bonding layer 640.

The anti-reflective layer ARP may include an organic material. For example, the anti-reflective layer ARP may include resin.

The anti-reflective layer ARP may serve to reduce fringe or reflection of light.

In case that the anti-reflective layer ARP is applied in a tape form, the anti-reflective layer ARP may include an adhesive layer (for example, OCA, OCR, and the like) on the backplate layer 400, and an anti-reflective film on the adhesive layer. However, in case that the anti-reflective layer ARP is applied in a tape form, it may have been difficult to completely fill up the hole in the plate layer 500 because the adhesive layer on which the anti-reflective film is attached has to be attached to the backplate layer 400. In particular, in case that the anti-reflective layer ARP is applied in a tape form, a tolerance between a width of a groove of the plate layer 500 and a width of the anti-reflective layer would occur in the tape form.

Further, a liner is attached to the anti-reflective film, and the liner has to be peeled off after attaching the anti-reflective layer in the tape form to the backplate layer 400, and in the peel-off step of the liner, there was a problem in that blister (or, bubble) may be generated between an inside of the adhesive layer or the adhesive layer and the backplate layer 400.

However, the anti-reflective layer ARP according to an embodiment includes resin, and the anti-reflective layer ARP is disposed in a manner of coating resin in the backplate layer 400 and the hole of the plate layer 500, and therefore, the anti-reflective layer ARP may fill up the hole of the plate layer 500. In particular, a width of the hole of the plate layer 500 and a width of the anti-reflective layer ARP may be the same. The anti-reflective layer ARP may be in direct contact with a side wall of the hole of the plate layer 500. The anti-reflective layer ARP may fill at least part of the hole of the plate layer 500.

Further, because the liner does not need to be attached and peeled off, it is possible to prevent occurrence of bubble between the inside of the anti-reflective layer ARP, or the anti-reflective layer ARP and the backplate layer 400.

A first sensor S1 may be disposed on the anti-reflective layer ARP. The first sensor S1 may be disposed in the first optical region SA1. The anti-reflective layer ARP may overlap the first sensor S1. The first sensor S1 may be an infrared sensor, but embodiments of the present disclosure are not limited thereto.

Light output from the first sensor S1 and light received by the first sensor S1 will be described below.

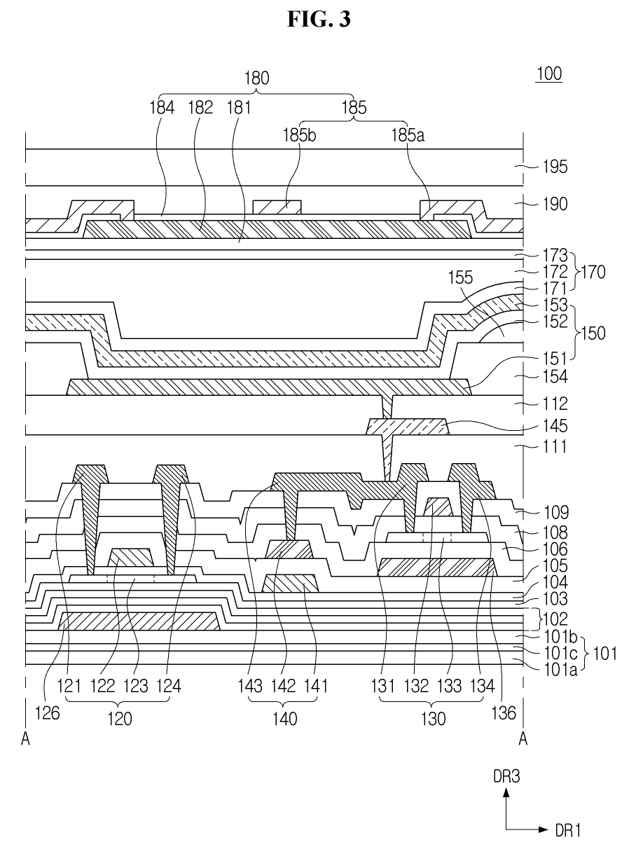

FIG. 3 is a schematic cross-sectional view of the display panel according to an embodiment.

Referring to FIG. 3, the display panel 100 may include a substrate 101, a first thin film transistor 120, a second thin film transistor 130, a light emitting unit 150, an encapsulation unit 170, a touch unit 180, and touch organic layers 190 and 195. The display panel 100 may include at least one inorganic panel layer and at least one touch inorganic layer between the substrate 101 and the light emitting unit 150. The at least one panel inorganic layer may include at least one among a buffer layer 102, a first insulation layer 103, a second insulation layer 104, a third insulation layer 105, a fourth insulation layer 106, a fifth insulation layer 108, and a sixth insulation layer 109 which will be described below, and the at least one touch inorganic layer may include at least one among a touch buffer layer 181 and an insulation layer 184.

The substrate 101 may include at least one or more plastic material. For example, the substrate 101 may be a multi-substrate which includes a plurality of plastic materials such as polyimide and the like. For example, the substrate 101 may include a first substrate portion 101a and a second substrate portion 101b, each of which includes a plastic material, and a third substrate portion 101c including an inorganic material and disposed between the first substrate portion 101a and the second substrate portion 101b, but embodiments of the present disclosure are not limited thereto.

A first light shielding layer 126 may be disposed on the substrate 101. The first light shielding layer 126 may prevent transmission of light into a first semiconductor layer 123 of the first thin film transistor 120. For example, the first semiconductor layer 123 may overlap the first light shielding layer 126 in a third direction DR3 (or thickness direction). The first light shielding layer 126 may be a single layer or a multi-layer formed of one among molybdenum (Mo), aluminum (Al), chrome (Cr), nickel (Ni), neodymium (Nd), and copper (Cu), or an alloy thereof, but embodiments of the present disclosure are not limited thereto.

The buffer layer 102 may be disposed on the first light shielding layer 126 and the substrate 101. The buffer layer 102 may minimize or delay diffusion of moisture or oxygen permeating the substrate 101. The buffer layer 102 may be formed by alternately depositing silicon nitride (SiNₓ) and silicon oxide (SiOₓ) at least once, but embodiments of the present disclosure are not limited thereto.

The first insulation layer 103 may be disposed on the buffer layer 102. The first insulation layer 103 may prevent a short circuit between components of the first thin film transistor 120 and the first light shielding layer 126. The first insulation layer 103 may be formed of the same material as that of the buffer layer 102, but embodiments of the present disclosure are not limited thereto. For example, the first insulation layer 103 may be formed of an inorganic material such as silicon nitride (SiNₓ) and silicon oxide (SiOₓ), but embodiments of the present disclosure are not limited thereto.

The first thin film transistor 120 may be disposed on the first insulation layer 103. The first thin film transistor 120 may include a first source electrode 121, a first gate electrode 122, the first semiconductor layer 123, and a first drain electrode 124.

The first semiconductor layer 123 may be disposed on the first insulation layer 103. The first semiconductor layer 123 may include a metal oxide semiconductor such as Indium-Gallium-Zinc Oxide (IGZO) etc., and a silicon-based semiconductor material such as amorphous silicon or polycrystalline silicon, etc., but the embodiments of the present disclosure are not limited thereto. The first semiconductor layer 123 may include a channel region, a source region, and a drain region.

A polycrystalline semiconductor layer has higher mobility than an amorphous semiconductor layer and an oxide semiconductor layer, and thus, may consume less power and have excellent reliability. Therefore, the driving transistor may be formed as the polycrystalline semiconductor layer.

The second insulation layer 104 may be formed on the first semiconductor layer 123 and the first insulation layer 103. The second insulation layer 104 may be formed of the same material as that of the first insulation layer 103 and may prevent a short circuit between the first semiconductor layer 123 and other components of the first thin film transistor 120.

The first gate electrode 122 may be disposed on the second insulation layer 104. The first gate electrode 122 may be disposed on the second insulation layer 104 such that the first gate electrode 122 overlaps the channel region of the first semiconductor layer 123 in the third direction DR3. The first gate electrode 122 may be a single layer or a multi-layer which includes molybdenum (Mo), copper (Cu), titanium (Ti), aluminum (Al), chrome (Cr), gold (Au), nickel (Ni), neodymium (Nd), or a compound thereof, but embodiments of the present disclosure are not limited thereto. The first gate electrode 122 may be disposed together with a gate line.

The third insulation layer 105 may be disposed on the first gate electrode 122 and the second insulation layer 104. The third insulation layer 105 may be formed of the same material as that of the first insulation layer 103 or the second insulation layer 104, but embodiments of the present disclosure are not limited thereto.

The first source electrode 121 and the first drain electrode 124 may be disposed on the sixth insulation layer 109.

The first source electrode 121 and the first drain electrode 124 may be electrically connected to the first semiconductor layer 123 through a contact hole penetrating the second insulation layer 104, the third insulation layer 105, the fourth insulation layer 106, the fifth insulation layer 108, and the sixth insulation layer 109. The first source electrode 121 and the first drain electrode 124 may be formed of a metal material. For example, the first source electrode 121 and the first drain electrode 124 may be formed as a single layer or a multi-layer formed of one among molybdenum (Mo), aluminum (Al), chrome (Cr), gold (Au), titanium (Ti), nickel (Ni), neodymium (Nd), and copper (Cu), or an alloy thereof, but embodiments of the present disclosure are not limited thereto.

The first source electrode 121 and the first drain electrode 124 may be disposed together with a data line. For example, the data line may be formed of the same material and formed on the same layer as those of the first source electrode 121 and the first drain electrode 124, but embodiments of the present disclosure are not limited thereto.

A storage electrode 140 may be disposed while being spaced apart from the first thin film transistor 120 in the first direction DR1. The storage electrode 140 may include a first storage electrode 141, a second storage electrode 142, and a third storage electrode 143.

The first storage electrode 141 may be formed of the same material on the same layer as those of the first gate electrode 122, but embodiments of the present disclosure are not limited thereto.

The second storage electrode 142 may be disposed on the first storage electrode 141. The second storage electrode 142 may be disposed on the third insulation layer 105, and a capacitance may be formed with the third insulation layer 105 between the first storage electrode 141 and the second storage electrode 142 serving as a dielectric. The second storage electrode 142 may be formed of the same material as that of the first storage electrode 141, but embodiments of the present disclosure are not limited thereto. The third storage electrode 143 may be disposed on the sixth insulation layer 109 and be electrically connected to the second storage electrode 142 through a contact hole penetrating the fourth insulation layer 106, the fifth insulation layer 108, and the sixth insulation layer 109.

The second thin film transistor 130 may be disposed while being spaced apart from the first thin film transistor 120 and the storage electrode 140 in the first direction DR1. In particular, the storage electrode 140 may be disposed between the second thin film transistor 130 and the first thin film transistor 120. The second thin film transistor 130 may include the second source electrode 131, the second gate electrode 132, the second semiconductor layer 133, and the second drain electrode 134. The second source electrode 131 and the second drain electrode 134 may be disposed on the sixth insulation layer 109 and be electrically connected to the second semiconductor layer 133 through a contact hole penetrating the fifth insulation layer 108 and the sixth insulation layer 109.

The second light shielding layer 136 may be disposed on the same layer as the second storage electrode 142. For example, the second light shielding layer 136 and the second storage electrode 142 may be disposed on the third insulation layer 105.

The second light shielding layer 136 may prevent light proceeding toward the second semiconductor layer 133 in a manner similar to the first light shielding layer 126, and therefore, may prolong a use lifespan of the second thin film transistor 130. For example, the second semiconductor layer 133 may be disposed to overlap the second light shielding layer 136.

The fourth insulation layer 106 may be disposed on the second light shielding layer 136. The fourth insulation layer 106 may be the same material as that of the first insulation layer 103, the second insulation layer 104, or the third insulation layer 105, but embodiments of the present disclosure are not limited thereto.

The second semiconductor layer 133 may be disposed on the fourth insulation layer 106. The second semiconductor layer 133 may include a source region, a drain region, and a channel region between the source region and the drain region.

The second semiconductor layer 133 may include a metal oxide semiconductor such as Indium-Gallium-Zinc Oxide (IGZO) etc., and a silicon-based semiconductor material such as amorphous silicon or polycrystalline silicon, etc., but the embodiments of the present disclosure are not limited thereto.

The fifth insulation layer 108 may be disposed on the second semiconductor layer 133. The fifth insulation layer 108 may be the same material as that of the first insulation layer 103, the second insulation layer 104, the third insulation layer 105, or the fourth insulation layer 106, but the embodiments of the present disclosure are not limited thereto.

The second gate electrode 132 may be disposed on the fifth insulation layer 108.

The second gate electrode 132 may be formed of the same material as that of the first gate electrode 122. For example, the second gate electrode 132 may be formed as a single layer or a multi-layer which includes molybdenum (Mo), copper (Cu), titanium (Ti), aluminum (Al), chrome (Cr), gold (Au), nickel (Ni), neodymium (Nd), or a compound thereof, but embodiments of the present disclosure are not limited thereto.

The sixth insulation layer 109 may be disposed on the second gate electrode 132. The sixth insulation layer 109 may be the same material as that of the first insulation layer 103, the second insulation layer 104, the third insulation layer 105, the fourth insulation layer 106, or the fifth insulation layer 108, but embodiments of the present disclosure are not limited thereto.

The first source electrode 121, the first drain electrode 124, the third storage electrode 143, the second source electrode 131, and the second drain electrode 134 may be disposed on the sixth insulation layer 109.

The third storage electrode 143, the second source electrode 131, and the second drain electrode 134 may be formed of the same material as that of the first source electrode 121 and the first drain electrode 124, and may be formed on the same layer as that of the first source electrode 121 and the first drain electrode 124, but embodiments of the present disclosure are not limited thereto. For example, the third storage electrode 143, the second source electrode 131, and the second drain electrode 134 may be a single layer or a multi-layer which includes one among molybdenum (Mo), aluminum (Al), chrome (Cr), gold (Au), titanium (Ti), nickel (Ni), neodymium (Nd), and copper (Cu), or an alloy thereof, but embodiments of the present disclosure are not limited thereto. For example, the third storage electrode 143 and the second source electrode 131 may be directly connected, but embodiments of the present disclosure are not limited thereto.

The first thin film transistor 120 may be a driving transistor, and the second thin film transistor 130 may be a switching transistor, but the embodiments of the present disclosure are not limited thereto.

A first protection layer 111 may be disposed on the first source electrode 121, the first drain electrode 124, the third storage electrode 143, the second source electrode 131, and the second drain electrode 134.

The first protection layer 111 may planarize an upper side of the first thin film transistor 120 and may protect the first thin film transistor 120. The first protection layer 111 may be formed of an organic material. For example, the first protection layer 111 may be formed of an organic material which includes acrylic resin, epoxy resin, phenolic resin, polyamide resin, or polyimide resin, but the embodiments of the present disclosure are not limited thereto.

A second protection layer 112 may be disposed on the first protection layer 111. The second protection layer 112 may be formed of the same material as that of the first protection layer 111, but the embodiments of the present disclosure are not limited thereto.

A connection electrode 145 may be disposed between the first protection layer 111 and the second protection layer 112.

The connection electrode 145 may electrically connect the first thin film transistor 120 (or storage electrode 140, second thin film transistor 130) to the light emitting unit 150. The connection electrode 145 may be formed of the same material as that of the first source electrode 121 and the first drain electrode 124, but the embodiments of the present disclosure are not limited thereto.

The connection electrode 145 may be a single layer or a multi-layer which includes one among molybdenum (Mo), aluminum (Al), chrome (Cr), gold (Au), titanium (Ti), nickel (Ni), neodymium (Nd), and copper (Cu), or an alloy thereof, but embodiments of the present disclosure are not limited thereto.

The light emitting unit 150 may be disposed on the second protection layer 112. The light emitting unit 150 may include an anode electrode 151, an organic layer 152, and a cathode electrode 153.

The anode electrode 151 may be disposed on the second protection layer 112. The anode electrode 151 may be electrically connected to the first thin film transistor 120 through a contact hole formed on the second protection layer 112. The anode electrode 151 may be a reflecting electrode configured to reflect light, but embodiments of the present disclosure are not limited thereto. The anode electrode 151 may include a metal material having a high reflectance such as a stacked structure (Ti/Al/Ti) of aluminum (Al) and titanium (Ti), a stacked structure (ITO/Al/ITO) of aluminum (Al) and ITO (Indium Tin Oxide), or an APC alloy, and may be formed of a single layer or a multi-layer, but embodiments of the present disclosure are not limited thereto.

The organic layer 152 may be disposed on the anode electrode 151. The organic layer 152 may include one or more light emitting structures (or light emitting elements or an element) stacked on the anode electrode 151 in the order of a hole transfer layer and an electron transfer layer, or in the reverse order. For example, the hole transfer layer may include a hole transport layer, a hole injection layer, an electron blocking layer, a P-type electric charge generation layer or the like, but the embodiments of the present disclosure are not limited thereto. For example, the electron transfer layer may include an electron transport layer, an electron injection layer, a hole blocking layer, an N-type electric charge generation layer or the like, but the embodiments of the present disclosure are not limited thereto. The organic layer 152 may be an organic light emitting layer, an inorganic light emitting layer, a quantum dot light emitting layer, a micro light emitting diode, a micro-mini light emitting diode and the like, but the embodiments of the present disclosure are not limited thereto. For example, the organic layer 152 of the display panel 100 according to an embodiment of the present disclosure may include an organic light emitting layer. The organic layer 152 may include a red light emitting layer, a green light emitting layer, and a blue light emitting layer. The organic layer may further include a white light emitting layer, but the embodiments of the present disclosure are not limited thereto.

A cathode electrode 153 may be disposed on the organic layer 152. The cathode electrode 153 may be a transparent electrode configured to transmit light, but the embodiments of the present disclosure are not limited thereto. For example, the cathode electrode 153 may include a transparent conductive material or metal such as ITO (Indium Tin Oxide) or IZO (Indium Zinc Oxide) through which the visible light is transmitted, but the embodiments of the present disclosure are not limited thereto.

A bank 154 may be disposed to expose the anode electrode 151. The bank 154 may be disposed such that the bank 154 defines an opening (or a light emitting region) of the sub-pixel, and covers an edge portion (or a boundary portion) of the anode electrode 151. Each of the sub-pixel may include a red light emitting region, a green light emitting region, and a blue light emitting region. For example, the sub-pixel may be a pixel, but it is not limited to its term. The bank 154 may be formed of an organic material such as a material including a black pigment and the like, a benzocyclobutene resin, a polyimide resin, an acrylic resin, or photosensitive polymer, but the embodiments of the present disclosure are not limited. In case that the bank 154 is formed of a material including a black pigment, a black dye and the like, the bank 154 may be a black bank. In case that forming the bank 154 with a material including a black pigment, a black dye and the like, the bank 154 may block light from the outside or light reflected from the outside, thereby further improving luminance of the display device. A spacer 155 may be further disposed on the bank 154. The spacer 155 may be formed of the same material as that of the bank 154, but the embodiments of the present disclosure are not limited thereto.

The encapsulation unit 170 may be disposed on the light emitting unit 150. For example, the encapsulation unit 170 may be disposed on the light emitting unit 150 and the bank 154. The encapsulation unit 170 may include one or more insulation layers. For example, the encapsulation unit 170 may include a first encapsulation layer 171, a second encapsulation layer 172 disposed on the first encapsulation layer 171, and a third encapsulation layer 173 disposed on the second encapsulation layer 172. The encapsulation unit 170 may include one or more inorganic material layers and one or more organic material layers. For example, the first encapsulation layer 171 and the third encapsulation layer 173 may include an inorganic material, and the second encapsulation layer 172 may include an organic material, but the embodiments of the present disclosure are not limited thereto.

The touch unit 180 may be disposed on the encapsulation unit 170. For example, the touch buffer layer 181 may be disposed on the encapsulation unit 170. For example, the touch buffer layer 181 may be disposed on the third encapsulation layer 173. The touch buffer layer 181 may be formed of the same material as that of the buffer layer 102, but the embodiments of the present disclosure are not limited thereto. The insulation layer 184 may be disposed on the touch buffer layer 181. The insulation layer 184 may prevent an electric short between touch electrodes. The insulation layer 184 may be formed of silicon nitride (SiNₓ) and silicon oxide (SiOₓ) or a multi-layer formed thereof, but embodiments of the present disclosure are not limited thereto. A first touch electrode 185 may be disposed on the insulation layer 184. The first touch electrode 185 may include a first-a touch electrode 185a extending in the first direction DR1, and a first-b touch electrode 185b extending in the second direction which is different from the first direction DR1.

A second touch electrode 182 may be disposed between the touch buffer layer 181 and the insulation layer 184.

The second touch electrode 182 may be electrically connected to the first-a touch electrode 185a through a contact hole penetrating the insulation layer 184. For example, the first-a touch electrode 185a and the second touch electrode 182 may extend in the first direction DR1.

The first touch electrode 185 and the second touch electrode 182 may include a metal material. For example, the first touch electrode 185 and the second touch electrode 182 may be formed of titanium (Ti), nickel (Ni), aluminum (Al), or an alloy thereof, and may be formed of three layers such as titanium(Ti)/aluminum(Al)/titanium(Ti), but the embodiments of the present disclosure are not limited thereto.

The touch organic layers 190, 195 may be disposed on the touch unit 180.

Referring to FIG. 3, the display panel 100 may include the substrate 101, the first thin film transistor 120, the second thin film transistor 130, the light emitting unit 150, and the encapsulation unit 170. The display panel 100 may further include the storage electrode 140.

The substrate 101 may include one or more plastic materials. For example, the substrate 101 may be a multi-substrate which includes a plurality of plastic materials such as polyimide and the like, but the embodiments of the present disclosure are not limited thereto.

The first light shielding layer 126 may be disposed on the substrate 101. Hereinafter, a conductive layer on which the first light shielding layer 126 is disposed will be referred to as a first conductive layer. The first light shielding layer 126 may prevent transmission of light into the first semiconductor layer 123 of the first thin film transistor 120.

The buffer layer 102 may be disposed on the first light shielding layer 126. The buffer layer 102 may minimize or reduce diffusion of moisture or oxygen permeating the substrate 101.

The first insulation layer 103 may be disposed on the buffer layer 102. The first insulation layer 103 may prevent an electric short between components of the first thin film transistor 120 and the first light shielding layer 126. The first insulation layer 103 may be formed of the same material as that of the buffer layer 102, but the embodiments of the present disclosure are not limited thereto.

The first thin film transistor 120 may be disposed on the first insulation layer 103. The first thin film transistor 120 may include the first source electrode 121, the first gate electrode 122, the first semiconductor layer 123, and the first drain electrode 124.

The first semiconductor layer 123 may be disposed on the first insulation layer 103. The first semiconductor layer 123 may include a material such as an oxide semiconductor such as Indium-Gallium-Zinc Oxide (IGZO) etc., amorphous silicon, low temperature amorphous silicon, or polycrystalline silicon, etc., but the embodiments of the present disclosure are not limited thereto. The first semiconductor layer 123 may include a channel region, a source region, and a drain region.

The second insulation layer 104 may be disposed on the first semiconductor layer 123. The second insulation layer 104 may be formed of the same material as that of the first insulation layer 103, but the embodiments of the present disclosure are not limited thereto.

The first gate electrode 122 may be disposed on the second insulation layer 104. The first gate electrode 122 may be disposed on the second insulation layer 104 to overlap the channel region of the first semiconductor layer 123 in the third direction DR3. A conductive layer on which the first gate electrode 122 is disposed will be referred to as a second conductive layer. The storage electrode 140 may be disposed while being spaced apart from the first thin film transistor 120. The storage electrode 140 may include the first storage electrode 141, the second storage electrode 142, and the third storage electrode 143.

The first storage electrode 141 may be formed of the same material and on the same layer as those of the first gate electrode 122, and may be disposed on the second conductive layer, but the embodiments of the present disclosure are not limited thereto.

The third insulation layer 105 may be disposed on the first gate electrode 122 and the first storage electrode 141. The third insulation layer 105 may be formed of the same material as that of the first insulation layer 103 and the second insulation layer 104, but the embodiments of the present disclosure are not limited thereto.

The second storage electrode 142 may be disposed on the third insulation layer 105. A capacitance may be formed with the third insulation layer 105 disposed between the first storage electrode 141 and the second storage electrode 142 serving as a dielectric. Hereinafter, a conductive layer on which the second storage electrode 142 is disposed will be referred to as a third conductive layer.

The fourth insulation layer 106 may be disposed on the third conductive layer.

The first source electrode 121 and the first drain electrode 124 may be disposed on the fourth insulation layer 106.

The first source electrode 121 and the first drain electrode 124 may be electrically connected to the first semiconductor layer 123 through contact holes penetrating the second insulation layer 104, the third insulation layer 105, the fourth insulation layer 106, the fifth insulation layer 108, and the sixth insulation layer 109. The first source electrode 121 and the first drain electrode 124 may be formed of a metal material. Hereinafter, a conductive layer on which the first source electrode 121 and the first drain electrode 124 are disposed will be referred to as a fourth conductive layer.

The first source electrode 121 and the first drain electrode 124 may be disposed together with a data line. For example, the data line may be formed of the same material and formed on the same layer as those of the first source electrode 121 and the first drain electrode 124, but embodiments of the present disclosure are not limited thereto. The third storage electrode 143 of the storage electrode 140 may be further disposed on the fourth conductive layer. The third storage electrode 143 may be electrically connected to the second storage electrode 142 through a contact hole. The third storage electrode 143 may be omitted.

The first protection layer 111 may be disposed on the fourth conductive layer. The first protection layer 111 may planarize an upper side of the first thin film transistor 120 and may protect the first thin film transistor 120. The first protection layer 111 may be formed of an organic material.

The second protection layer 112 may be disposed on the first protection layer 111. The second protection layer 112 may be formed of the same material as that of the first protection layer 111, but the embodiments of the present disclosure are not limited thereto.

The connection electrode 145 may be disposed between the first protection layer 111 and the second protection layer 112. Hereinafter, a conductive layer on which the connection electrode 145 is disposed will be referred to as a fifth conductive layer.

The connection electrode 145 may electrically connect the first thin film transistor 120 (or storage electrode 140, second thin film transistor 130) to the light emitting unit 150. The connection electrode 145 may be formed of the same material as that of the first source electrode 121 and the first drain electrode 124, but the embodiments of the present disclosure are not limited thereto.

The light emitting unit 150 may be disposed on the second protection layer 112. The light emitting unit 150 may include the anode electrode 151, the organic layer 152, and the cathode electrode 153.

The anode electrode 151 may be disposed on the second protection layer 112. The anode electrode 151 may be electrically connected to the first thin film transistor 120 (or storage electrode 140, second thin film transistor 130) through a contact hole penetrating the second protection layer 112 and the first protection layer 111. The anode electrode 151 may be a reflecting electrode configured to reflect light, but embodiments of the present disclosure are not limited thereto. Hereinafter, a conductive layer on which the anode electrode 151 is disposed will be referred to as a sixth conductive layer.

The organic layer 152 may be disposed on the anode electrode 151. The organic layer 152 may include one or more light emitting structures (or light emitting elements or an element) stacked on the anode electrode 151 in the order of a hole transfer layer and an electron transfer layer, or in the reverse order.

The cathode electrode 153 may be disposed on the organic layer 152. The cathode electrode 153 may be a transparent electrode configured to transmit light, but the embodiments of the present disclosure are not limited thereto.

The bank 154 may be disposed to expose the anode electrode 151. The bank 154 may be disposed such that the bank 154 defines an opening (or a light emitting region) of the sub-pixel and covers an edge portion (or a boundary portion) of the anode electrode 151.

The pixel may include a plurality of sub-pixels. Each of the pixels may include a red light emitting region, a green light emitting region, and a blue light emitting region which correspond to the plurality of sub-pixels. As another example, the pixel may further include a white light emitting region, but the embodiments of the present disclosure are not limited. The bank 154 may be formed of an organic material such as a material including a black pigment and the like, a benzocyclobutene resin, a polyimide resin, an acrylic resin, or photosensitive polymer, but the embodiments of the present disclosure are not limited.

The encapsulation unit 170 may be disposed on the light emitting unit 150. For example, the encapsulation unit 170 may be disposed on the bank 154. The encapsulation unit 170 may include one or more insulation layers. For example, the encapsulation unit 170 may include the first encapsulation layer 171, the second encapsulation layer 172 disposed on the first encapsulation layer 171, and the third encapsulation layer 173 disposed on the second encapsulation layer 172. The encapsulation unit 170 may include one or more inorganic material layers and one or more organic material layers. For example, the first encapsulation layer 171 and the third encapsulation layer 173 may include an inorganic material, and the second encapsulation layer 172 may include an organic material, but the embodiments of the present disclosure are not limited thereto.

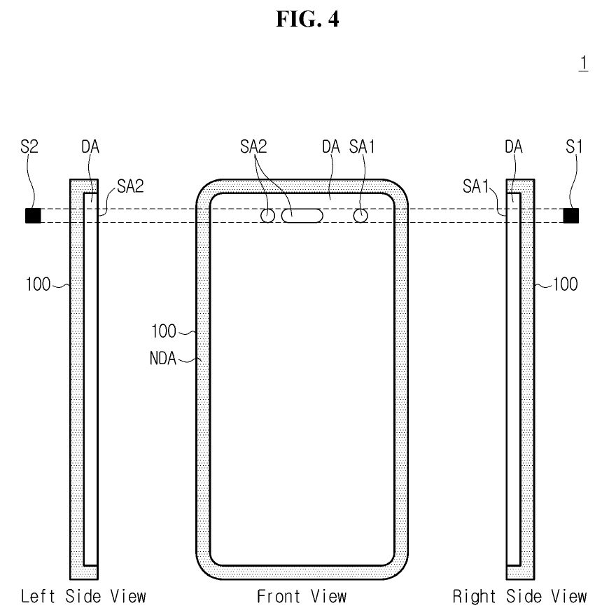

FIG. 4 is a schematic schematic plan view of the display device according to an embodiment.

According to the example of FIG. 4, the optical regions SA1 and SA2 may be surrounded by the display region DA. At least part of the first optical region SA1 may overlap the first sensor S1, and at least part of the second optical region SA2 may overlap the second sensor S2.

In the one or more optical regions SA1 and SA2, both an image display structure and the light transmitting structure may be formed. In particular, the sub-pixel for displaying an image must be disposed in the one or more optical regions SA1 and SA2. In the one or more optical regions SA1 and SA2, the light transmitting structure for allowing light to be transmitted to the one or more sensors S1 and S2 must be formed.

The one or more sensors S1 and S2 may be devices which need light reception, however, they are positioned on a rear side of the display panel 100 (below, an opposite side of a viewing surface), and receive light which has passed through the display panel 100.

The one or more sensors S1 and S2 may not be exposed to a front surface (a viewing surface) of the display panel 100. Therefore, in case that a user views the front surface of the display device 1, the sensors S1 and S2 may not be visible to the user.

The display region DA and the one or more optical regions SA1 and SA2 may be regions capable of displaying images, however, the display region DA does not need the light transmitting structure, and the one or more optical regions SA1 and SA2 need the light transmitting structure to be formed therein.

Therefore, the one or more optical regions SA1 and SA2 may have a transmittance above a certain level, while the display region DA may not have the light transmittance or may have a low light transmittance which is less than a certain level.

For example, a resolution, an arrangement structure of the sub-pixel, a quantity of the sub-pixels per unit area, an electrode structure, a line structure, an arrangement structure of the electrodes, an arrangement structure of the lines, or the like of the one or more optical regions SA1 and SA2 and those of the display region DA may be different from each other.

For example, the quantity of the sub-pixels per unit area in the one or more optical regions SA1 and SA2 may be fewer than the quantity of the sub-pixels per unit area in the display region DA. In particular, the resolution of the one or more optical regions SA1 and SA2 may be lower than the resolution of the display region DA. For example, the quantity of the sub-pixels per unit area may be a unit for measuring the resolution, and may be Pixels Per Inch (PPI), which means a quantity of the pixels in one inch.

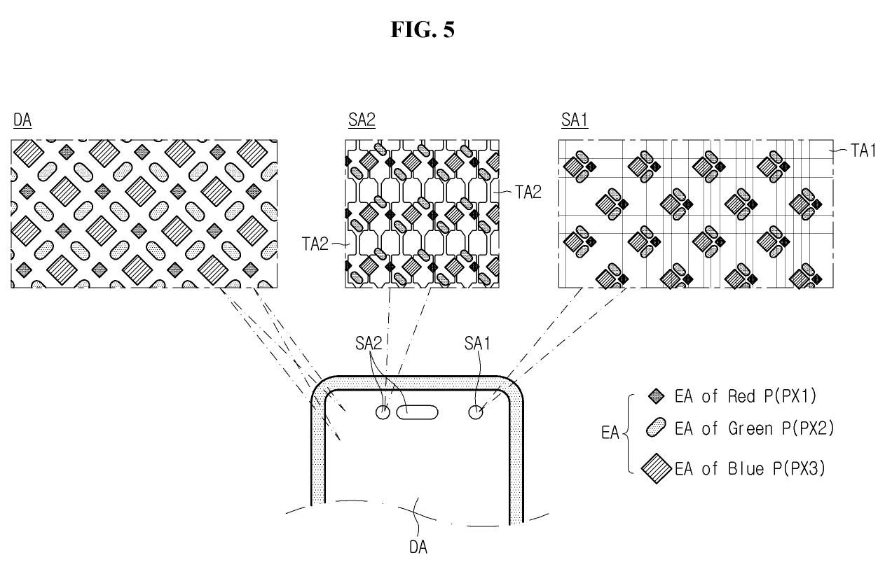

FIG. 5 is a schematic view illustrating an arrangement of the sub-pixel in the display region, the first optical region, and the second optical region according to an embodiment.

Referring to FIG. 5, the plurality of sub-pixels may be disposed in each of the display region DA, the first optical region SA1 and the second optical region SA2.

For example, the plurality of sub-pixels may include a red sub-pixel Red SP (or a first sub-pixel PX1) configured to emit red light, a green sub-pixel Green SP (or a second sub-pixel PX2) configured to emit green light, and a blue sub-pixel Blue SP (or a third sub-pixel PX3) configured to emit blue light. In FIG. 5, a planar shape of the plurality of sub-pixels are illustrated to be a square shape, or an oval shape, but the embodiments of the present disclosure are not limited thereto, and may be a circular shape.

Therefore, each of the display region DA, the first optical region SA1 and the second optical region SA2 may include an emitting region EA of the red sub-pixel Red SP, an emitting region EA of the green sub-pixel Green SP, and an emitting region EA of the blue sub-pixel Blue SP.

Referring to FIG. 5, the display region DA may not include the light transmitting structure, but may include the emitting region EA. However, the first optical region SA1 and the second optical region SA2 must include not only the emitting region EA, but also the light transmitting structure.

Therefore, the first optical region SA1 may include the emitting region EA and a first transmitting region TA1, and the second optical region SA2 may include the emitting region EA and a second transmitting region TA2.

The emitting region EA and the transmitting regions TA1 and TA2 may be distinguished from each other according to light transmission availability. In particular, the emitting region EA may be a region through which light cannot pass and the transmitting regions TA1 and TA2 may be regions through which light can pass.

In addition, the emitting region EA and the transmitting regions TA1 and TA2 may be distinguished from each other according to presence of a certain metal layer. For example, the cathode electrode may be formed in the emitting region EA, and the cathode electrode may not be formed in the transmitting regions TA1 and TA2. In addition, the light shielding layer may be formed in the emitting region EA, but the light shielding layer may not be formed in the transmitting regions TA1 and TA2.

For example, as the first optical region SA1 may include the first transmitting region TA1 and the second optical region SA2 includes the second transmitting region TA2, both the first optical region SA1 and the second optical region SA2 may be regions through which light can pass.

For example, a transmittance (a degree of transmission) of the first optical region SA1 and a transmittance (a degree of transmission) of the second optical region SA2 may be the same.

For example, a shape or a size of the first transmitting region TA1 of the first optical region SA1 and the second transmitting region TA2 of the second optical region SA2 may be the same. In particular, even if a shape or a size of the first transmitting region TA1 of the first optical region SA1 and the second transmitting region TA2 of the second optical region SA2 are not the same, a ratio of the first transmitting region TA1 in the first optical region SA1 and a ratio of the second transmitting region TA2 in the second optical region SA2 may be the same. Unlike the above, the transmittance (a degree of transmission) of the first optical region SA1 and the transmittance (a degree of transmission) of the second optical region SA2 may be different from each other. For example, a shape or a size of the first transmitting region TA1 of the first optical region SA1 and the second transmitting region TA2 of the second optical region SA2 may be different from each other. In some embodiments, even if a shape or a size of the first transmitting region TA1 of the first optical region SA1 and the second transmitting region TA2 of the second optical region SA2 are the same, a ratio of the first transmitting region TA1 in the first optical region SA1 and a ratio of the second transmitting region TA2 in the second optical region SA2 may be different from each other.

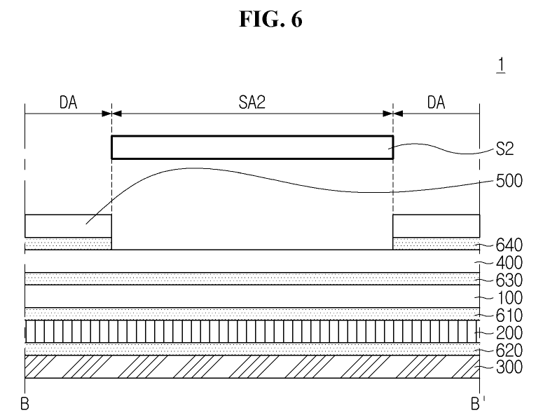

FIG. 6 is a schematic cross-sectional view taken along line B-B’ in FIG. 1.

Referring to FIG. 6, the second sensor S2 may be disposed in the second optical region SA2. The second sensor S2 may be a camera sensor, but the embodiments of the present disclosure are not limited thereto. In the second optical region SA2, the anti-reflective layer ARP which has been described referring to FIG. 2 may not be disposed.

In some embodiments, an anti-reflective structure may be applied in the second optical region SA2, but the anti-reflective structure may be different from the anti-reflective layer ARP applied in the first optical region SA1. For example, the anti-reflective structure disposed in the second optical region SA2 may be applied in a form of a tape. For example, the anti-reflective structure may include the adhesive layer (for example, OCA, OCR, etc.) on the backplate layer 400, and a reflection preventing film on the adhesive layer.

For example, in case that a width of the second optical region SA2 is greater than a width of the first optical region SA1, an anti-reflective structure different from that of the first optical region SA1 may be applied in the second optical region SA2. In particular, in case that the width of the second optical region SA2 is greater than the width of the first optical region SA1, an area of the second optical region SA2 which is covered by the anti-reflective structure may become wider because the width of the second optical region SA2 is greater compared to the width of the first optical region SA1 even if there is a tolerance between a width of the hole of the plate layer 500 and a width of a groove of the anti-reflective structure taking the form of a tape.

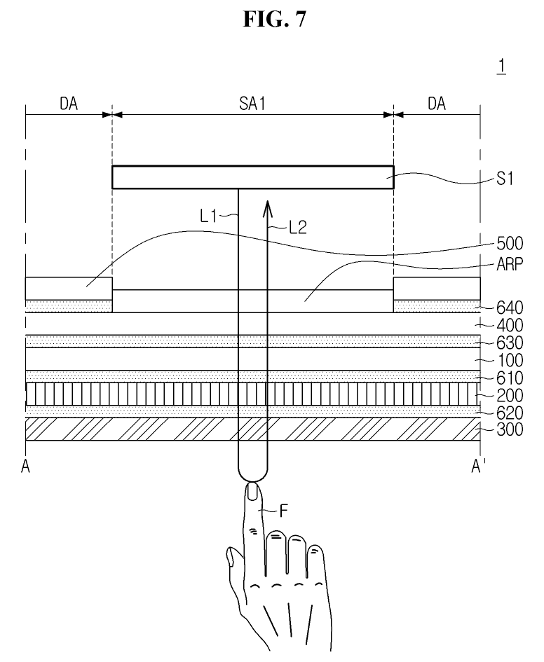

FIG. 7 is a schematic view illustrating light output from the sensor and light received by the sensor of the display device according to an embodiment.

Referring to FIG. 7, light L1 output from the first sensor S1 may pass through the display device, be reflected from the user (or an object) (in FIG. 7, a finger F of the user is illustrated) and may be proceeded to the display device again (refer to L2). Light L2 reflected from the user (or finger F) may pass through the cover layer 300, the second bonding layer 620, the polarization layer 200, the first bonding layer 610, the display panel 100, the third bonding layer 630, and the backplate layer 400, and may reach the anti-reflective layer ARP.

In case that the anti-reflective layer ARP is not disposed, on an interface of the backplate layer 400 and the air, the light L2 may be diffracted, or reflected and thus, the amount of light received by the first sensor S1 may decrease. However, according to the display device according to an embodiment, as the anti-reflective layer ARP is disposed on the backplate layer 400, fringe or reflection of the light L2 may be minimized, thereby the light reception efficiency of the first sensor S1 may increase.

For example, the refractive index of the anti-reflective layer ARP may have a value between a refractive index of the backplate layer 400 and a refractive index of the air. Because of this, an interface of the backplate layer 400 and the anti-reflective layer ARP and an interface of the anti-reflective layer ARP and the air, fringe, or reflection of the light L2 may be prevented. For example, the refractive index of the anti-reflective layer ARP may be greater than that of the air, and smaller than that of the backplate layer 400.

In addition, as described above, because the anti-reflective layer ARP includes the resin, the anti-reflective layer ARP may cover an entire region of the hole of the plate layer 500. As a result, fringe or reflection of the light L2 may be further prevented.

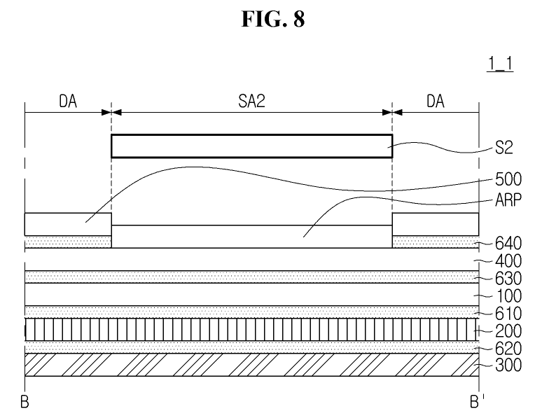

FIG. 8 is a schematic cross-sectional view of a display device according to another embodiment.

Referring to FIG. 8, the anti-reflective layer ARP which has been described referring to FIG. 2 may be additionally disposed in the second optical region SA2 of a display device 1_1 according to an embodiment. The anti-reflective layer ARP may overlap the second sensor S2 in the thickness direction. The anti-reflective layer ARP may be in direct contact with a side wall of the hole of the plate layer 500. The anti-reflective layer ARP may be in direct contact with a top surface of the backplate layer 400, a side surface of the plate layer 500 adjacent thereto, and the fourth bonding layer 640.

The anti-reflective layer ARP may include an organic material. For example, the anti-reflective layer ARP may include the resin. The anti-reflective layer ARP may serve to reduce fringe or reflection of light in the second optical region SA2 as well.

Description on other components has been provided referring to FIG. 2, and therefore, description in detail thereof will be omitted.

The display device according to various embodiments of the present disclosure may be described as below.

The display panel of the display device according to embodiments may improve light reception efficiency of the sensor by designing a quantity of the pixels in the optical region to be fewer than a quantity of the pixels in the display region.

The display device according to embodiments may minimize fringe (or reflection) of light received by the sensor by disposing the anti-reflective layer in the optical region below the plate layer.

The display device according to embodiments may allow the anti-reflective layer to fill up the hole of the plate layer by configuring the anti-reflective layer to include resin.

The display device according to embodiments may provide a low-power display device because the bubble phenomenon is prevented.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a display panel including a display region and an optical region which is disposed around the display region;
a backplate layer disposed on the display panel;
a plate layer disposed on the backplate layer in the display region; and
an anti-reflective layer disposed on the backplate layer in the optical region,
wherein the anti-reflective layer includes resin.

2. The display device of claim 1, wherein the anti-reflective layer is in direct contact with a top surface of the backplate layer.

3. The display device of claim 1, wherein the anti-reflective layer is in direct contact with a side surface of the plate layer.

4. The display device of claim 1, wherein the plate layer includes a hole defined in the optical region, and
wherein a width of the hole is identical to a width of the anti-reflective layer.

5. The display device of claim 4, wherein the anti-reflective layer is in contact with a side wall of the hole of the plate layer.

6. The display device of claim 4, wherein the anti-reflective layer fills at least part of the hole of the plate layer.

7. The display device of claim 1, wherein a refractive index of the anti-reflective layer has a value between a refractive index of the backplate layer and a refractive index of air.

8. The display device of claim 1, further comprising a sensor disposed on the anti-reflective layer in the optical region.

9. The display device of claim 8, wherein the anti-reflective layer overlaps the sensor in a thickness direction.

10. The display device of claim 8, wherein the sensor is an infrared sensor.

11. The display device of claim 4, wherein the anti-reflective layer covers an entire region of the hole of the plate layer.

12. A display device, comprising:
a display panel including a display region and an optical region surrounded by the display region;
a backplate layer disposed on the display panel;
a plate layer disposed on the backplate layer in the display region; and
an anti-reflective layer disposed on the backplate layer in the optical region,
wherein the display panel includes:
a substrate;
a first thin film transistor disposed on the substrate;
a second thin film transistor disposed on the substrate and spaced apart from the first thin film transistor;
a light emitting unit disposed on the substrate;
an encapsulation unit disposed on the light emitting unit;
a touch unit disposed on the encapsulation unit; and
touch organic layers disposed on the touch unit.

13. The display device of claim 12, further comprising a storage electrode disposed between the first thin film transistor and the second thin film transistor.

14. The display device of claim 12, wherein the touch unit includes:
a touch buffer layer disposed on the encapsulation unit;
a second touch electrode disposed on the touch buffer layer;
an insulation layer disposed on the second touch electrode; and
a first touch electrode disposed on the insulation layer.

15. The display device of claim 14, wherein the first touch electrode includes:
a first-a touch electrode extending in a first direction; and
a first-b touch electrode extending in a second direction which is different from the first direction, and
wherein the first-b touch electrode is electrically connected to the second touch electrode through a contact hole penetrating the insulation layer.

16. The display device of claim 12, wherein the anti-reflective layer is in direct contact with a top surface of the backplate layer.

17. The display device of claim 12, wherein the anti-reflective layer is in direct contact with a side surface of the plate layer.

18. The display device of claim 12, wherein the plate layer includes a hole defined in the optical region, and
wherein a width of the hole is identical to a width of the anti-reflective layer.

19. The display device of claim 18, wherein the anti-reflective layer is in contact with a side wall of the hole of the plate layer.

20. The display device of claim 18, wherein the anti-reflective layer fills at least part of the hole of the plate layer.
